(19) United States
(12) Patent Application Publication
(10) Pub. No.: US 2026/0059670 A1
(43) Pub. Date: Feb. 26, 2026

(54) Housing and Method for Closing a Housing

(71) Applicant: KNORR-BREMSE Systeme fuer Nutzfahrzeuge GmbH, Muenchen (DE)

(72) Inventors: Alexander RAMMERT, Muenchen (DE); Christian KAUFMANN, Schwieberdingen (DE); Manuel STEGMANN, Stuttgart (DE); Frank SCHOLL, Ingersheim (DE); Dominick Willi Hermann FUNK, Eisingen (DE); Alexander MATT, Bruchsal (DE); Matthias ROTH, Vaihingen an der Enz (DE); Guenter HERRMANN, Stuttgart (DE); Emirhan ATMACA, Abstatt (DE)

(21) Appl. No.: 19/305,888

(22) Filed: Aug. 21, 2025

(30) Foreign Application Priority Data
Aug. 22, 2024 (DE) 10 2024 123 984.0

(51) Int. Cl. H05K 5/00; H05K 5/02

(52) U.S. Cl. CPC H05K 5/0052; H05K 5/0247

(57) ABSTRACT

A housing for at least one component having a first housing part and a second housing part which can be connected to each other to close the housing is disclosed. The housing has a mechanical component having a first connection and a second connection to connect the mechanical component inside the housing to the first housing part and to the second housing part of the housing, wherein the second connection is designed to be weaker than the first connection and breakage of the second connection indicates opening of the housing.

### CROSS REFERENCE TO RELATED APPLICATION

This application claims priority under 35 U.S. C. § 119 from German Patent Application No. 10 2024 123 984.0, filed Aug. 22, 2024, the entire disclosure of which is herein expressly incorporated by reference.

### BACKGROUND AND SUMMARY

The present invention relates to a housing and a method for closing a housing, to a utility vehicle having the housing and, in particular, to a detection of opened housings by means of exemplary spring contacts, wires or similar components.

Cybersecurity is becoming increasingly important, especially in the automotive sector, where high security standards must be ensured. This includes protecting electronic components or electronic systems from manipulations. This is to be ensured in that housings in which the electronic components are accommodated cannot be easily opened or that unauthorized opening can at least be determined. It should thus be determined at least in retrospect that a potential attacker has penetrated or wished to penetrate the housing. For example, intrusion could allow the attacker to change the operation of the electronic system in an unauthorized manner. These unauthorized changes include, for example, tuning, installing malware or other changes that change the driving mode of the vehicle in an unauthorized manner.

Conventional devices for determining the opening of a housing are, for example, the application of a seal or an adhesive bond to the device housing, which then break upon opening. If this is determined retrospectively, it may lead to a guarantee or a warranty being invalidated. However, this does not provide protection against misuse or the above-mentioned tuning. Moreover, these seals/adhesive bonds could be repaired again afterwards.

Other conventional solutions use so-called gate contacts (for example in a cover), which electronically report access. But even for these measures, potential attackers learn to bypass these obvious measures.

Therefore, there is a need for further measures to at least detect unwanted or unauthorized access to an electronic housing-even if access cannot be ruled out in principle.

At least one of the above-mentioned problems is solved by a housing and by a method for closing the housing according to the independent claim(s). The dependent claims define further advantageous embodiments of the subject matter of the independent claims.

The present invention relates to a housing for at least one component. The housing comprises a first housing part and a second housing part which can be connected to each other to close the housing. The housing further comprises a mechanical component having a first connection and a second connection to connect the mechanical component inside the housing to the first housing part and to the second housing part of the housing. The second connection is designed to be weaker than the first connection and breakage of the second connection indicates opening of the housing.

It will be understood that the first and/or the second connection(s) may be formed directly or indirectly (for example via a printed circuit board) to connect both housing parts via the mechanical component (directly or indirectly). In addition, the more weakly designed second connection can be formed as a predetermined breaking point and be configured to be as invisible as possible. The component may, for example, have at least one electronic component. For example, it can be a printed circuit board with electrical components.

Optionally, the mechanical component is a spring contact between the second housing part and the at least one component. The second connection may be or comprise at least one of the following: a welded connection, soldered connection or adhesive connection. For example, the first connection can contact or be fastened to the component.

Optionally, the housing comprises a detector which is designed to send an electrical signal through the mechanical component and to signal opening of the housing from a change in the electrical signal. For example, the mechanical component may contain a metal and be part of a signal line which is firmly connected on one side to the first housing part and on another side to the second housing part, so that when the housing is opened, the signal line is interrupted. The detector can send a signal over the signal line and infer opening of the housing from a broken signal line.

Exemplary embodiments also relate to a (further) housing for at least one component having a first housing part and a second housing part which can be connected to each other to close the housing. The (further) housing comprises a detector for an electromagnetic signal within the housing, wherein the detector is designed to signal opening of the housing from a change in the electromagnetic signal.

Optionally, the electromagnetic signal is at least one of the following: visible light, infrared signal, an electrical voltage, an electrical signal, a magnetic signal, a capacitance (changing a distance changes the capacitance) or an electromagnetic wave (for example a radio signal).

Optionally, the detector comprises a first detector component and a second detector component, between which the electromagnetic signal propagates. One of the detector components is firmly connected to the first housing part and the other is firmly connected to the second housing part. The first detector component and/or the second detector component comprise at least one of the following:
a radiation source and a photodiode (for example for receiving a signal from the radiation source, so that the detector can infer opening of the housing from a change in the received signal),
a high-frequency identification, RFID, transponder and an RFID reader (for example, one of them can be formed on or in the first housing part and the other may be formed on or in the second housing part or on the component, so that a relative movement between the two starts a reading process of the transponder and the detector infers opening of the housing therefrom),
a Hall sensor and a magnet (for example, one of them can be formed on or in the first housing part and the other of them can be formed on or in the second housing part or the component, so that the detector infers opening of the housing from a change in a sensor signal of the Hall sensor).

Optionally, the detector (only) comprises a photodiode for receiving a signal (for example light) from the surroundings of the housing if the housing is opened. In turn, the detector can infer opening of the (further) housing from a change in a sensor signal from the photodiode.

Optionally, the detector comprises a data store and is designed to output a warning in response to a detected opening of the housing or to store information about the opening in the data store (for example, a flag can be set).

Optionally, the component comprises a functional component for a predetermined function, wherein the predetermined function can change (or is no longer available) in response to the warning or the stored information.

Optionally, the detector is formed invisibly in the housing (for example embedded in a material of the housing and/or of the component in the housing).

Optionally, the first housing part is a base element having a printed circuit board as component fastened thereto. Optionally, the second housing part is a cover element for closing the base element.

Exemplary embodiments also relate to a utility vehicle (for example a truck or bus) having a previously defined housing. The housing can accommodate a vehicle control unit.

Exemplary embodiments also relate to a method for closing a housing for at least one component. The method comprises:
providing a first housing part and a second housing part;
closing the housing by joining together the first housing part and the second housing part; and
fixing a mechanical component to the first housing part and via a predetermined breaking point to the second housing part inside the housing, so that opening of the housing leads to breakage of the predetermined breaking point.

Optionally, the fixing step comprises at least one of the following fastenings: welding, soldering or adhesive bonding, wherein, for example, the following can be carried out: ultrasonic welding, electrical heating, localized heating or application of adhesive and curing of the adhesive after closing the housing.

It will be understood that all of the above-described optional components of the housings can be implemented as further optional method steps in the production of a closed housing. It will also be understood that the listing sequence does not necessarily mean a sequence in which the method steps are performed. The steps may also be performed in another sequence or only some of the method steps are performed.

Exemplary embodiments have a large number of advantages. Thus, at least some of the above-mentioned problems are solved by the fact that components (for example the mechanical component or the detector) or parts thereof which can determine opening of the housing and can output corresponding messages can be designed to be virtually invisible. Thus, the mechanical component may be detectable after opening, but not the breakage of a fixed connection of the mechanical component on the first and/or the second housing part.

Exemplary embodiments may use different types of sensors based on different technical principles. These sensors can be divided into active sensors (for example energized) and passive sensors (non-energized) or electronic and non-electronic sensors. Non-electronic sensors include, for example, mechanical precautions which determine opening of the housing. Active electronic sensors include, for example, sensors which transmit an electrical signal and determine opening of the housing upon a change in the electrical signal. Passive electronic sensors include, for example, such sensors which detect incident light after opening of the housing and determine the opening of the housing based on this.

Exemplary embodiments use in particular detection devices or a detector which can not only indicate opening of the housing but also prevents or limits an operation after an unauthorized opening or a possible modification or initiates monitoring. Thus, for example, highly sensitive functions (for example autonomous driving) could be paused after determining an unauthorized opening of the associated control device. The driver could activate this mode again only when corresponding monitoring has been carried out.

The exemplary embodiments of the present invention will be better understood from the following detailed description and the attached drawings of the various exemplary embodiments, which however are not intended to be understood such that they restrict the disclosure to the specific embodiments, but rather serve merely for the purposes of explanation and understanding.

### BRIEF DESCRIPTION OF THE DRAWINGS

FIG. 1 shows a housing according to one exemplary embodiment of the present invention.

FIG. 2 shows a further housing according to further exemplary embodiments.

FIG. 3 is a schematic flow diagram for a procedure for closing a housing according to exemplary embodiments.

### DETAILED DESCRIPTION OF THE DRAWINGS

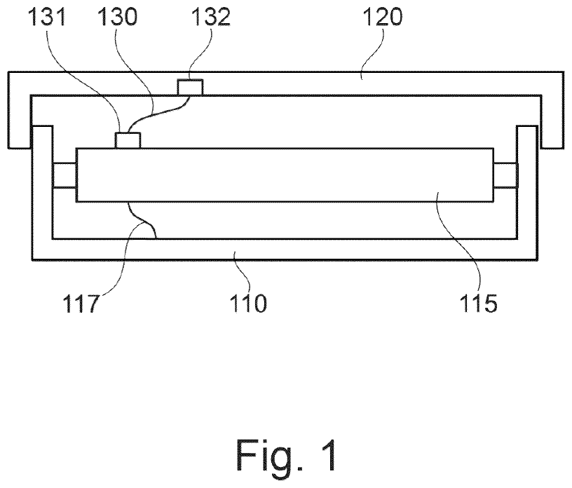

FIG. 1 shows an exemplary embodiment for a housing for a component 115. The housing comprises a first housing part 110 and a second housing part 120 which can be connected to each other to close the housing, as shown. The housing further comprises a mechanical component 130, which establishes a connection between the first housing part 110 and the second housing part 120. The component 115 may be or have a printed circuit board or an electronic component. The component 115 can be firmly connected to the first housing part 110. The mechanical component 130 thus indirectly connects the first housing part 110 to the second housing part 120 (via the component 115). The component 115 may in particular comprise a component which controls a certain function in the vehicle (for example as a vehicle control unit).

According to exemplary embodiments, the mechanical component 130 is a spring or has a spring action which presses the exemplary component 115 in the vertical direction against the first housing part 110. This ensures that the component 115 is securely held. The mechanical component 130 may have a first connection 131 and a second connection 132, wherein the second connection 132 provides a firm connection to the second housing part 120 (for example by spot welding or soldering or adhesive bonding) and the first connection 131 firmly couples the mechanical component 130 to the component 115 or to the first housing part 110.

According to exemplary embodiments, the second connection 132 can provide a predetermined breaking point. To ensure this, the first connection 131 can be firmly connected to the component 115 or hook in there, wherein the connection to the component 115 can be designed to be stronger than the second connection 132 to the second housing part 120. Therefore, upon opening of the housing, this second connection 132 to the second housing part 120 breaks—but not the first connection 131 to the component 115 (or to the first housing part 110). The breakage of the predetermined breaking point 132 can be determined later, even if the housing has been closed again in the meantime. Thus, unauthorized access to the components 115 present in the housing can be determined retrospectively. The determination can also occur without reopening. Thus, for example, imaging methods such as X-ray or ultrasound examinations can be used to determine the breakage of the predetermined breaking point even without opening.

Advantageously, the breakage of the predetermined breaking point 132 is not immediately detectable. For this purpose, the second connection 132 between the mechanical component 130 and the second housing part 120 can be designed to be correspondingly small (for example occupying an area of less than 1 mm in diameter), so that, for example, microscopic examinations would have to be carried out in order to detect the existing predetermined breaking point 132. A potential attacker will not be able to readily determine that a firm connection 132 between the mechanical component 130 and the second housing part 120 (for example cover) has existed at all. On the other hand, however, it could be determined by ultrasound examinations or X-rays or by electrical measurements before the opening of the housing whether the second connection 132 between the mechanical components 130 and the second housing part 120 has been broken (for example by an unauthorized opening).

According to further exemplary embodiments, the housing may be energized. Energized housings can either be connected to an external current source (via optional connecting contacts or connecting plugs, not shown in FIG. 1) or have their own battery. When the housing is energized, an electrical current can be sent through the mechanical component 130, which interrupts upon opening of the housing and outputs a corresponding signal. Exemplary embodiments therefore comprise an optional detector which is designed to determine the signal through the mechanical component 130 and (for example in the event of interruption) to output a warning or to store as information in a store (for example to set a marker or a flag). This could cause the component 115 or a functional component in the housing to show a different operation than was previously the case. For example, unauthorized opening can lead to the deactivation of certain features in order to safely rule out manipulations. For example, autonomous driving can be made more difficult or impossible if it is not ruled out that a potential attacker has obtained access to the control electronics.

The first housing part 110 may, for example, contain a metal (for example cast aluminum). In this case, an optional ground contact 117 may be provided which connects a rear side of the component 115, for example, to the first housing part 110. The second housing part 120 can form a cover and also contain a metal. However, it can also be made of a plastics material (for example polyamide).

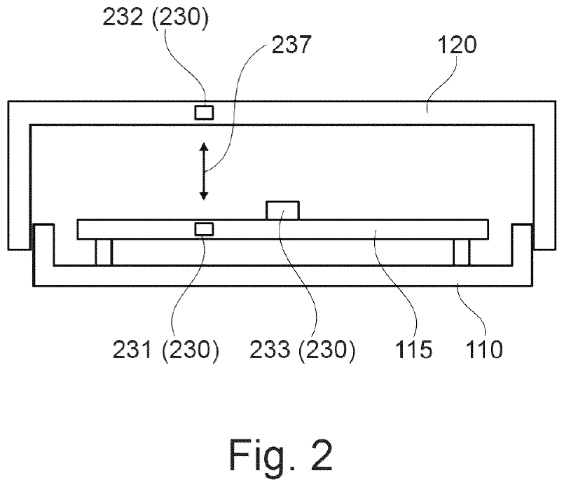

FIG. 2 shows further details of an energized housing as can be present according to exemplary embodiments. The energized housing either has its own voltage source (for example battery or accumulator) or is connected to an external voltage source via a connection. The external voltage source may, for example, be a battery of the exemplary vehicle (for example utility vehicle or truck).

According to this embodiment, the housing in turn comprises a first housing part 110, a second housing part 120 and a detector 230. The detector 230 can be arranged, for example, on or in the component 115. The detector 230 can in particular also be completely embedded in the component 115 (for example be potted in a printed circuit board), so that its existence does not need to be visible after opening of the housing.

Optionally, the detector comprises a first detector component 231, a second detector component 232, and an optional data store 230. The first detector component 231 and/or the second detector component may comprise or be at least one of the following: a light-emitting diode, a photodiode, a radiation source, an RFID chip, a Hall sensor, a mirror or a magnet. The first or second detector component 231, 232 may be an active component and the respective other may be a passive component. For example, the second detector component 232 may be potted or embedded as a passive component in the second housing part 120 (for example if it contains a plastic) so that it is not visible after opening of the housing. One or more detection results may be logged in the data store 230.

According to exemplary embodiments, an electromagnetic signal 237 is exchanged between the first detector component 231 and the second detector component 232. The electromagnetic signal 237 may comprise, for example, a light signal, an infrared signal, a magnetic signal, a radio frequency signal (radio signal) or another electromagnetic signal, which allows the detector 230 to determine opening of the housing from a change in the signal.

According to exemplary embodiments, the first detector component 231 and the second detector component 232 each comprise an RFID chip, one of which is embedded in the second housing part 120 (cover) and the other RFID chip is mounted in or on the first housing part 110 or the component 115 (it could also be invisibly integrated there). The housing may, for example, contain a dielectric material, so that a corresponding signal propagation between the two RFID chips is possible without problems. One of the RFID chips may be a transponder and the other may be an associated reader. In this case, the electromagnetic signal 237 is the transponder signal.

According to exemplary embodiments, the first detector component 231 is a radiation source and the second detector component 232 is a photodiode. The second detector component 232 may also be a mirror, in which case a photodiode is additionally formed on the component 115. The detector 230 can infer opening of the housing from a change in the received signal.

According to exemplary embodiments, the detector 230 (only) comprises a photodiode for receiving a signal (for example light) from the surroundings of the housing if the housing is opened. In turn, the detector 230 can infer opening of the (further) housing from a change in a sensor signal from the photodiode.

According to exemplary embodiments, the detector 230 comprises a Hall sensor as first detector component 231 and a magnet as second detector component 232. In this case, the detector 230 can infer opening of the housing from a change in a sensor signal from the Hall sensor. In this case, the electromagnetic signal 237 is a change in the magnetic field from the magnet 232 in the exemplary cover 120.

According to exemplary embodiments, the detector 230 can form a capacitor which changes its capacitance upon opening. Thus, the first detector component 231 may be a first capacitor electrode and the second detector component 231 may be a second capacitor electrode, which move away from each other upon opening and thus can cause a detection signal.

Advantageously, the detector 230 or its individual components 231, 232 is arranged such that they are not readily detectable for an intruder or potential attacker after opening of the housing. This can be achieved, for example, in that the detector components 231, 232 are embedded in the material of the housing parts 110, 120 or the component 115 (for example melted into a polymer material).

According to exemplary embodiments, opening of the housing may lead to a change in the behavior of the device in question (for example the functional component in the housing). Alternatively or in addition, a warning can be output (for example in real time to an external device) or recorded in a data store 233 and read out later (for example in a workshop). It can thus be determined whether a manipulation has possibly been carried out.

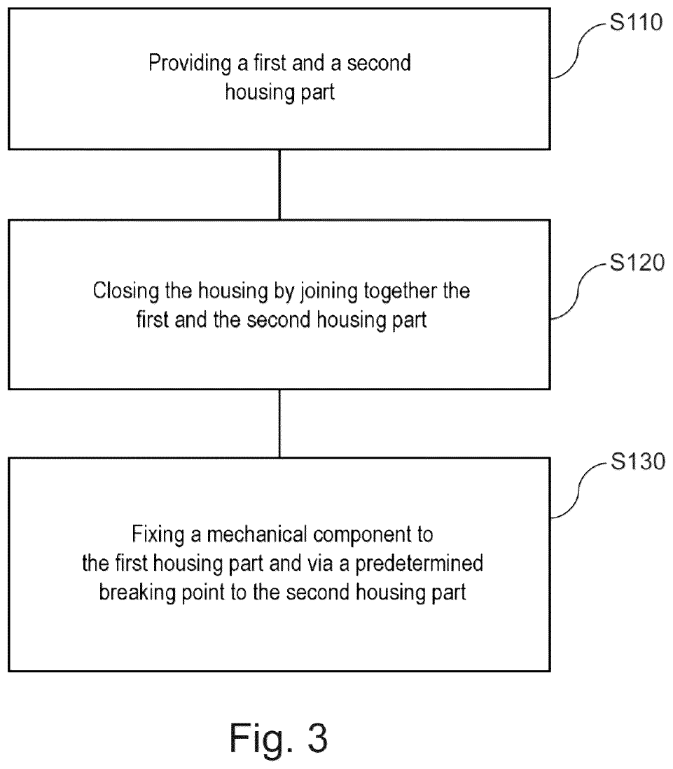

FIG. 3 shows a schematic flow diagram for a procedure for closing a housing according to exemplary embodiments. The method comprises the following steps:
providing S110 a first housing part 110 and a second housing part 120;
closing S110 the housing by joining together the first housing part 110 and the second housing part 120; and
fixing S130 a mechanical component 130 to the first housing part 110 and via a predetermined breaking point 132 to the second housing part 120 inside the housing, so that opening of the housing leads to breakage of the predetermined breaking point 132.

Fixing may comprise welding, soldering or adhesive bonding. In particular, this step can be carried out after closing the housing. If, on the other hand, the mechanical component 130 is also firmly fixed to the first housing part 110 (for example also by welding, soldering or adhesive bonding), the housing can only be opened if at least one of these connections 131, 132 is broken. Preferably, this can be the connection 132 to the second housing part 120. This can be achieved in that this second connection 132 is formed as a predetermined breaking point (for example designed to be weaker or smaller than the first connection 231). This offers the advantage that an optional check can be performed before opening of the housing. For this purpose, non-invasive material examinations can be carried out (for example, ultrasound, X-ray, electrical measurement) in order to determine a breakage of the second connection 132 on the exemplary cover (second housing part).

Essential aspects of the exemplary embodiment can be summarized as follows. Exemplary embodiments can be divided into two groups:
(1) energized housings (for example comprise a battery or are connected to a vehicle battery);
(2) non-energized housings.

Group (1) includes, for example, the exemplary embodiments which detect opening of the housing by means of a photosensor in order to detect extraneous light (from outside the housing) when the housing is open. A further possibility for energized devices is the presence of a photodiode and a light-emitting diode, which transmits a specific light spectrum, so that in turn extraneous light is detectable as a disturbance of the transmitted light spectrum. A further possibility in this group lies in the use of a Hall sensor, which can be soldered, for example, on a printed circuit board, and of a magnet, which, for example, is invisibly potted in the second housing part 120 (for example in the removable cover). If the cover 120 is opened, the change in the magnetic field results in a change in the signal from the Hall sensor, which in turn can be detected as opening of the housing. The evaluation of the energized group of housings can be performed by an existing microcontroller.

Group (2) of exemplary embodiments includes housings which do not have access to a current source or generate the required current themselves. This includes, for example, said RFID chips (for example transponders, readers), which, for example, can be invisibly incorporated (for example potted) in a printed circuit board 115 or arranged invisibly in the cover (second housing part 120). By a relative movement of the two detector components 131, 132, they generate their own current (for example by induction) in order to trigger a detection signal. Advantageously, a potential attacker (intruder) does not detect that protective measures are provided, so that no countermeasures are taken or learnt. A further embodiment for the protection of non-energized housings is to arrange a mechanical component 130 with a predetermined breaking point 132 in the housing. Here, too, the predetermined breaking point 132 cannot be detected as such (for example designed to be very small). Thus, for example, a spring contact, which at first glance looks like a clamping device for the exemplary printed circuit board 115, can, for example, be firmly connected to the cover by means of an ultrasonic welding process. This can be done, for example, after closing the housing. Upon later opening of the housing, the (small) welding contact will tear off without this being immediately detectable. The spring contact may be disguised as a preloading device which continues to function after unauthorized opening and closing.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

### LIST OF REFERENCE SIGNS

110 First housing part
115 At least one component (for example printed circuit board, functional component)
117 Earth connection
120 Second housing part
130 Mechanical component
131 First connection
132 Second connection (for example predetermined breaking point)
230 Detector
231 First detector component
232 Second detector component
237 Electromagnetic signal (detection signal)
233 Data store

What is claimed is:

1. A housing for at least one component, comprising:
a first housing part and a second housing part which are connected to each other to close the housing; and
a mechanical component having a first connection and a second connection to connect the mechanical component inside the housing to the first housing part and to the second housing part of the housing,
wherein the second connection is configured to be weaker than the first connection and breakage of the second connection indicates opening of the housing.

2. The housing according to claim 1, wherein
the mechanical component is a spring contact between the second housing part and the component, and
the second connection is at least one of: a welded connection, a soldered connection, or an adhesive connection.

3. The housing according to claim 1, further comprising:
a detector, which is configured to send an electrical signal through the mechanical component and to signal opening of the housing from a change in the electrical signal.

4. A housing for at least one component, comprising:
a first housing part and a second housing part which are connectable to each other to close the housing; and
a detector for an electromagnetic signal within the housing,
wherein the detector is configured to signal opening of the housing from a change in the electromagnetic signal.

5. The housing according to claim 4, wherein
the electromagnetic signal is at least one of: visible light, infrared signal, an electrical voltage, an electrical signal, a magnetic signal, a capacitance or an electromagnetic wave.

6. The housing according to claim 4, wherein
the detector has a first detector component and a second detector component, between which the electromagnetic signal propagates, and
one of the first or second detector components are firmly connected to the first housing part and the other is firmly connected to the second housing part,
wherein the first detector component and the second detector component have at least one of:
a radiation source and a photodiode,
a high-frequency identification, RFID, transponder and an RFID reader, or
a Hall sensor and a magnet.

7. The housing according to claim 4, wherein the detector has a photodiode for receiving a signal from an environment of the housing when the housing is open.

8. The housing according to claim 4, wherein
the detector has a data store and is configured, in response to a detected opening of the housing, to output a warning or to store information about the opening in the data store.

9. The housing according to claim 8, wherein
the component has a functional component for a predetermined function, which is designed to change the predetermined function in response to the warning or the stored information.

10. The housing according to claim 3, wherein
the detector has a data store and is configured, in response to a detected opening of the housing, to output a warning or to store information about the opening in the data store.

11. The housing according to claim 4, wherein the detector is configured to be invisible in the housing.

12. The housing according to claim 3, wherein the detector is configured to be invisible in the housing.

13. The housing according to claim 1, wherein
the first housing part is a base element with a printed circuit board as the component fastened thereto, and
the second housing part is a cover element for closing the base element.

14. The housing according to claim 4, wherein
the first housing part is a base element with a printed circuit board as the component fastened thereto, and
the second housing part is a cover element for closing the base element.

15. A utility vehicle comprising a housing according to claim 1.

16. A utility vehicle comprising a housing according to claim 4.

17. A method for closing a housing for at least one component, comprising:
providing a first housing part and a second housing part;
closing the housing by joining together the first housing part and the second housing part; and
fixing a mechanical component to the first housing part and, via a predetermined breaking point, to the second housing part inside the housing, so that opening of the housing leads to breakage of the predetermined breaking point.

18. The method according to claim 17, wherein the step of fixing at least comprises one of: welding, soldering or adhesive bonding.
